(19) United States
(12) Patent Application Publication
(10) Pub. No.: US 2022/0260765 A1
(43) Pub. Date: Aug. 18, 2022

(54) LIGHT EMITTING DEVICE

(71) Applicants: PIONEER CORPORATION, Bunkyo-ku, Tokyo (JP); TOHOKU PIONEER CORPORATION, Tendo-shi, Yamagata (JP)

(72) Inventor: Shinji NAKAJIMA, Yonezawa-shi, Yamagata (JP)

(21) Appl. No.: 17/641,057

(22) PCT Filed: Sep. 3, 2020
(86) PCT No.: PCT/JP2020/033407

§ 371 Date: Mar. 7, 2022

(30) Foreign Application Priority Data
Sep. 10, 2019 (JP) 2019164327

(51) Int. Cl. G02B 5/20; G02B 5/30; H01L 27/32

(52) U.S. Cl. CPC G02B 5/20; H01L 27/3237; H01L 27/322; G02B 5/3025

(57) ABSTRACT

A color filter portion (200) (first color filter portion (200a)) overlaps with some light emitting portions (140) (first light emitting portion (140a) and second light emitting portion (140b)) of a plurality of light emitting portions (140), and does not overlap with some other light emitting portions (140) (third light emitting portion (140c)) of the plurality of light emitting portions (140). Thus, the second surface (104) of the substrate (100) includes a region where a color filter portion is not positioned, the region overlapping with at least one light emitting portion (140) (third light emitting portion (140c)) of the plurality of light emitting portions (140) when viewed from a direction perpendicular to a first surface (102) or a second surface (104) (region overlapping with the third light emitting portion (140c) when viewed from the direction perpendicular to the first surface (102) or the second surface (104)).

### TECHNICAL FIELD

The present invention relates to a light emitting device.

### BACKGROUND ART

In recent years, as disclosed in, for example, Patent Document 1 or 2, a color filter portion may be used to color light emitted from a light emitting device. The light emitting devices disclosed in Patent Documents 1 and 2 include a substrate, a plurality of light emitting portions, and a plurality of color filter portions. The plurality of light emitting portions are positioned over a first surface of the substrate. The plurality of color filter portions are positioned over a second surface opposite to the first surface of the substrate. Each light emitting portion is a pixel of an image. The plurality of color filter portions include three types of color filter portions of a red (R) color filter portion, a green (G) color filter portion, and a blue (B) color filter portion. Each of the plurality of color filter portions overlaps with each of the plurality of light emitting portions.

### RELATED DOCUMENT

### Patent Document

[Patent Document 1] Japanese Unexamined Patent Publication No. 2001-167874
[Patent Document 2] Japanese Unexamined Patent Publication No. 2011-119091

### SUMMARY OF THE INVENTION

### Technical Problem

The present inventor has studied to easily color the light emitted from some light emitting portions in the light emitting device.

Examples of the problem to be solved by the present invention include easily coloring the light emitted from some light emitting portions in the light emitting device.

### Solution to Problem

The invention according to claim 1 relates to a light emitting device including a translucent substrate including a first surface and a second surface opposite to the first surface, a plurality of light emitting portions positioned over the first surface of the substrate, and a first color filter portion positioned over the second surface of the substrate and overlapping with at least one light emitting portion of the plurality of light emitting portions when viewed from a direction perpendicular to the first surface or the second surface, in which the second surface of the substrate includes a region where a color filter portion is not positioned, the region overlapping with at least one light emitting portion of the plurality of light emitting portions when viewed from the direction perpendicular to the first surface or the second surface.

The invention according to claim 2 relates to a light emitting device including a translucent substrate including a first surface and a second surface opposite to the first surface, a plurality of light emitting portions positioned over the first surface of the substrate, and a first color filter portion positioned over the second surface of the substrate and overlapping with at least two light emitting portions of the plurality of light emitting portions when viewed from a direction perpendicular to the first surface or the second surface.

The invention according to claim 10 relates to a light emitting device including a translucent substrate including a first surface and a second surface opposite to the first surface, a plurality of light emitting portions positioned over the first surface of the substrate, a first color filter portion positioned over the second surface of the substrate and overlapping with at least one light emitting portion of the plurality of light emitting portions when viewed from a direction perpendicular to the first surface or the second surface, and a polarizing plate covering the second surface of the substrate and the first color filter portion and adhered to the second surface of the substrate through an adhesive, in which the second surface of the substrate includes a region in contact with the adhesive, the region overlapping with at least one light emitting portion of the plurality of light emitting portions when viewed from the direction perpendicular to the first surface or the second surface.

The invention according to claim 11 relates to a light emitting device including a translucent substrate including a first surface and a second surface opposite to the first surface, a plurality of light emitting portions positioned over the first surface of the substrate, a first color filter portion positioned over the second surface of the substrate and overlapping with at least one light emitting portion of the plurality of light emitting portions when viewed from a direction perpendicular to the first surface or the second surface, a polarizing plate covering the second surface of the substrate and the first color filter portion and adhered to the second surface of the substrate through an adhesive, and a transparent resin covered with the adhesive around the first color filter portion, in which the second surface of the substrate includes a region in contact with at least one of the adhesive and the transparent resin, the region overlapping with at least one light emitting portion of the plurality of light emitting portions when viewed from the direction perpendicular to the first surface or the second surface.

### BRIEF DESCRIPTION OF THE DRAWINGS

FIG. 1 is a plan view of a light emitting device according to Embodiment 1.

FIG. 2 is a view with an organic layer and a second electrode removed from FIG. 1.

FIG. 3 is a cross-sectional view taken along line A-A of FIG. 1.

FIG. 4 is a view for describing an example of a function of a color filter portion (first color filter portion) according to Embodiment 1.

FIG. 5 is a view for describing another example of the function of the color filter portion (first color filter portion) according to Embodiment 1.

FIG. 6 is a plan view of a light emitting device according to Embodiment 2.

FIG. 7 is a cross-sectional view taken along line A-A of FIG. 6.

FIG. 8 is a view for describing an example of functions of a plurality of color filter portions (first color filter portion and second color filter portion) according to Embodiment 2.

FIG. 9 is an enlarged cross-sectional view of a part of the light emitting device according to Example 1.

FIG. 10 is an enlarged cross-sectional view of a part of the light emitting device according to Example 2.

FIG. 11 is an enlarged cross-sectional view of a part of the light emitting device according to Example 3.

FIG. 12 is an enlarged cross-sectional view of a part of the light emitting device according to Example 4.

FIG. 13 is a plan view of a second surface of a substrate of a light emitting device according to Example 5.

### DESCRIPTION OF EMBODIMENTS

An expression “A is positioned over B” in the present specification may mean that A is directly positioned on B with no different element (for example, a layer) positioned between A and B or may mean that a different element (for example, a layer) is partially or fully positioned between A and B. Furthermore, expressions indicating orientations, such as “up”, “down”, “left”, “right”, “front”, and “back” are basically used in accordance with orientations in the drawings and are not interpreted to be limited to, for example, orientations in which an invented product described in the present specification is used.

In the present specification, the expression “A and B overlap with each other” means that at least a part of A is positioned at the same place as at least a part of B on a projection image from a certain direction, unless otherwise noted. In this case, a plurality of elements may be directly in contact with each other or may be spaced from each other.

An anode in the present specification refers to an electrode from which a hole is injected into a layer containing a light emitting material (for example, an organic layer) and a cathode refers to an electrode from which an electron is injected into the layer containing the light emitting material. In addition, expressions “anode” and “cathode” may also mean different terms such as “hole injection electrode” and “electron injection electrode” or “positive electrode” and “negative electrode”.

“Light emitting device” in the present specification includes devices having a light emitting element such as a display, lighting, or the like. In addition, “light emitting device” may include wires, integrated circuits (ICs), casing, or the like that are directly, indirectly, or electrically connected to the light emitting element.

In the present specification, unless otherwise noted, the expression “film” and the expression “layer” can be appropriately replaced depending on a situation and a case. For example, the term “insulating film” can be replaced with the term “insulating layer”.

The expression “connect” in the present specification refers to a state in which a plurality of elements are directly or indirectly connected. For example, a case where a plurality of elements are connected through an adhesive or a joining member may also be simply expressed as “a plurality of elements are connected”. In addition, a case where a member capable of supplying or transmitting a current, a voltage, or a potential is present between a plurality of elements and “a plurality of elements are electrically connected” may also be simply expressed as “a plurality of elements are connected”.

In the present specification, unless otherwise noted, expressions such as “first, second, A, B, (a), and (b)” and the like are expressions for differentiating elements, and the essence, sequence, order, number, or the like of the corresponding element is not limited by the expression.

In the present specification, each member and each element may be singular or plural, unless the context clarifies whether a member or element is “singular” or “plural”.

In the present specification, unless otherwise noted, the expression “A includes B” does not necessarily mean that A consists of B and possibly means that A may consist of element other than B.

Unless otherwise noted, “cross section” in the present specification means a surface that appears at the time of cutting the light emitting device in a direction in which pixels, light emitting materials, or the like are laminated.

In the present specification, the expressions “not have”, “not include”, “not positioned”, and the like may mean that a certain element is completely excluded, or may mean that an element is present to the extent that it does not have a technical effect.

In the present specification, expressions that describe anteroposterior relations in time such as “after”, “subsequent to”, “next”, and “before” indicate relative time relations, and individual elements for which an anteroposterior relation in time is used are not necessarily continuous from each other. In the case of expressing individual elements that are continuous from each other, an expression “immediately”, “directly”, or the like may be used.

Unless otherwise noted, the expression “A covers B” in the present specification may mean, for example, that A contacts with B with no other elements (for example, a layer) positioned between A and B or may mean that other elements (for example, a layer) are partially or fully positioned between A and B.

In the following, embodiments of the present invention will be described below with reference to the drawings. It should be noted that, in all drawings, similar components are designated by the similar reference numerals, and the description thereof will not be repeated.

### Embodiment 1

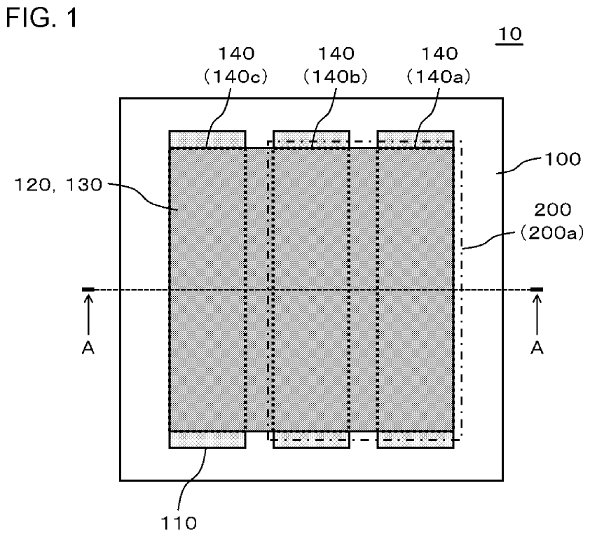

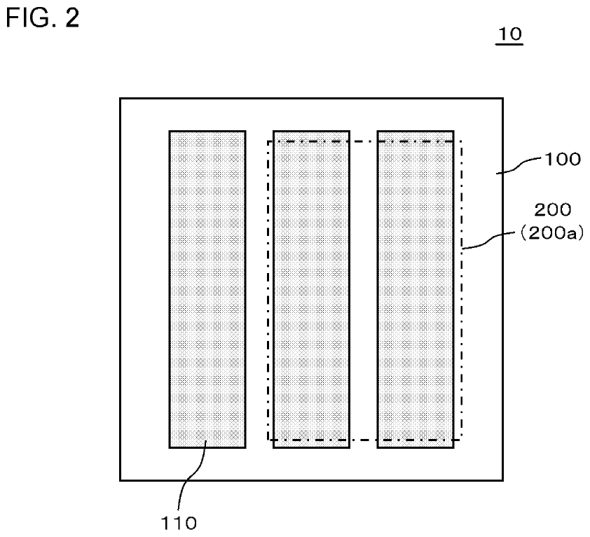

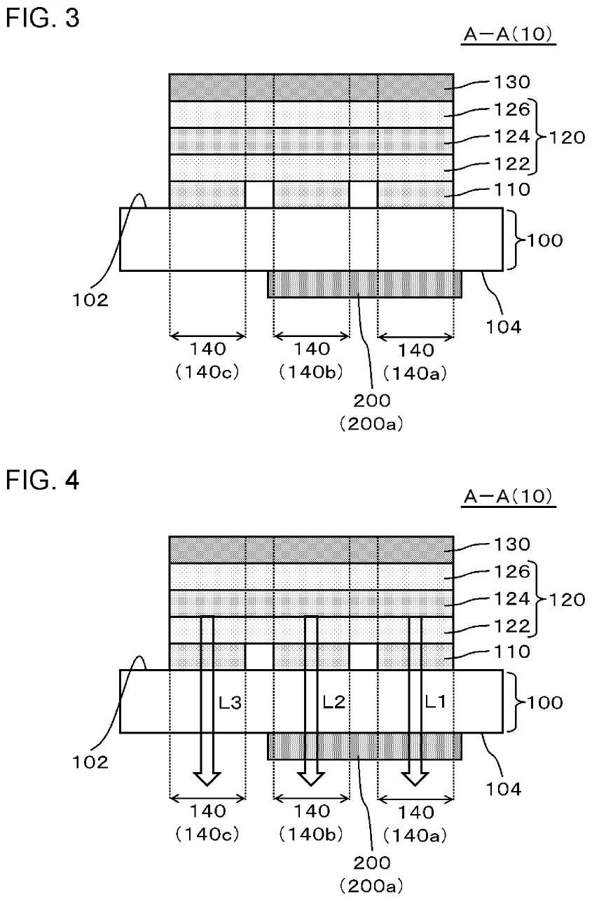

FIG. 1 is a plan view of a light emitting device 10 according to Embodiment 1. FIG. 2 is a view with an organic layer 120 and a second electrode 130 removed from FIG. 1. FIG. 3 is a cross-sectional view taken along line A-A of FIG. 1.

The light emitting device 10 includes a substrate 100, a plurality of light emitting portions 140 (a plurality of first electrodes 110, the organic layer 120, and the second electrode 130), and a color filter portion 200 (first color filter portion 200a).

The substrate 100 has translucency. A transmittance of the visible light of the substrate 100 is, for example, equal to or more than 75% and equal to or less than 100%. The substrate 100 may be a single layer or a plurality of layers. A thickness of the substrate 100 is, for example, equal to or more than 10 μm and equal to or less than 1000 μm. The substrate 100 has a first surface 102 and a second surface 104. The plurality of first electrodes 110, the organic layer 120, and the second electrode 130 are positioned over the first surface 102 of the substrate 100. The second surface 104 is positioned opposite to the first surface 102. The color filter portion 200 is positioned over the second surface 104 of the substrate 100. The substrate 100 is a glass substrate, for example. The substrate 100 may be a resin substrate containing an organic material (for example, polyethylene naphthalate (PEN), polyethersulfone (PES), polyethylene terephthalate (PET), or polyimide). When the substrate 100 is the resin substrate, an inorganic barrier layer (for example, SiN or SiON) may be positioned over at least one of the first surface 102 and the second surface 104 of the substrate 100.

The plurality of first electrodes 110 are positioned over the first surface 102 of the substrate 100. The plurality of first electrodes 110 are spaced apart from each other. Each first electrode 110 has translucency. A transmittance of the visible light of each first electrode 110 is, for example, equal to or more than 75% and equal to or less than 100%. Each first electrode 110 can function as the anode. In an example, the first electrode 110 may contain metal or alloy. The metal or the alloy is silver or a silver alloy, for example. In this example, a thickness of the first electrode 110 may be, for example, equal to or more than 5 nm and equal to or less than 50 nm. When the thickness of the first electrode 110 is equal to or more than the lower limit described above, the electrical resistance of the first electrode 110 can be decreased, and when the thickness of the first electrode 110 is equal to or less than the upper limit described above, the transmittance of the first electrode 110 can be increased. In another example, the first electrode 110 may contain an oxide semiconductor. Examples of the oxide semiconductor include indium tin oxide (ITO), indium zinc oxide (IZO), indium tungsten zinc oxide (IWZO), zinc oxide (ZnO), and indium galium zinc oxide (IGZO).

The organic layer 120 is positioned over the plurality of first electrodes 110. The organic layer 120 includes a hole transport layer (HTL) 122, an emissive layer (EML) 124 and an electron transport layer (ETL) 126. The HTL 122, the EML 124, and the ETL 126 overlap with the plurality of first electrodes 110. In other words, the HTL 122, the EML 124, and the ETL 126 continuously extend over the plurality of first electrodes 110. The EML 124 emits, for example, white light by organic electroluminescence (EL). A structure of the layer contained in the organic layer 120 is not limited to a structure according to the present embodiment. For example, the organic layer 120 may further include at least one of a hole injection layer (HIL) and an electron injection layer (EIL), or may further include a charge generation layer (CGL).

The second electrode 130 is positioned over the organic layer 120. The second electrode 130 overlaps with the plurality of first electrodes 110. In other words, the second electrode 130 continuously extends over the plurality of first electrodes 110. The second electrode 130 can function as the cathode. In an example, the second electrode 130 may contain metal or alloy. The metal or alloy is, for example, at least one metal selected from the group consisting of Al, Au, Ag, Pt, Mg, Sn, Zn, and In, or an alloy of the metal selected from the group described above.

In the present embodiment, the plurality of light emitting portions 140 are physically spaced apart from each other, and can be switched on (light emitting state) or off (non-light emitting state) independently of each other. Specifically, the plurality of light emitting portions 140 are positioned over the first surface 102 of the substrate 100, and have a laminate of the first electrode 110, the organic layer 120, and the second electrode 130. The plurality of light emitting portions 140 are spaced apart from each other in accordance with the plurality of first electrodes 110 spaced apart from each other. That is, each light emitting portion 140 has each first electrode 110, a portion of the organic layer 120 overlapping with each first electrode 110, and a portion of the second electrode 130 overlapping with each first electrode 110. The voltage can be applied to the first electrodes 110 independently of each other. Accordingly, the plurality of light emitting portions 140 can be switched on (light emitting state) or off (non-light emitting state) independently of each other.

A structure of the plurality of light emitting portions 140 is not limited to a structure according to the present embodiment. For example, a plurality of second electrodes 130 may be spaced apart from each other over the common first electrode 110 and the common organic layer 120. In this case, the plurality of light emitting portions 140 are spaced apart from each other in accordance with the plurality of second electrodes 130 spaced apart from each other. That is, each light emitting portion 140 has a portion of the first electrode 110 overlapping with each second electrode 130, a portion of the organic layer 120 overlapping with each second electrode 130, and each second electrode 130. The voltage can be applied to the second electrodes 130 independently of each other. Accordingly, the plurality of light emitting portions 140 can be switched on (light emitting state) or off (non-light emitting state) independently of each other.

Each of the plurality of light emitting portions 140 is a segment type light emitting portion. Each light emitting portion 140, however, may not be a segment type light emitting portion, and may be, for example, a pixel of an image.

The plurality of light emitting portions 140 are sealed by a sealing member (for example, a glass sealing can or a metal sealing can) or a sealing film (for example, an inorganic insulating film) not shown.

The color filter portion 200 (first color filter portion 200a) overlaps with some light emitting portions 140 (first light emitting portion 140a and second light emitting portion 140b) of a plurality of light emitting portions 140, and does not overlap some other light emitting portions 140 (third light emitting portion 140c) of the plurality of light emitting portions 140. Thus, the second surface 104 of the substrate 100 includes a region where a color filter portion is not positioned, the region overlapping with at least one light emitting portion 140 (third light emitting portion 140c) of the plurality of light emitting portions 140 when viewed from the direction perpendicular to the first surface 102 or the second surface 104 (region overlapping with the third light emitting portion 140c when viewed from the direction perpendicular to the first surface 102 or the second surface 104). In the present embodiment, the color filter portion is a dye-containing element (for example, a layer) through which visible light is transmittable, and gives the color indicated by the dye to the visible light transmitted through the element.

The color filter portion 200 contains, for example, at least one of a cyan (C) dye, a magenta (M) dye, and a yellow (Y) dye. In this example, the color filter portion 200 is made of three primary colors (CMY) of color. When the color filter portion 200 is made of the three primary colors (CMY) of color, the color variation of the color filter portion 200 can be increased as compared with when the color filter portion 200 is made of three primary colors (RGB) of light. Further, when the color filter portion 200 is made of the three primary colors (CMY) of color, a wavelength band of the light transmittable through the color filter portion 200 can be widened, and the efficiency of extracting the light from the color filter portion 200 can be improved, as compared with when the color filter portion 200 is made of the three primary colors (RGB) of light. The color filter portion 200, however, may be made of the three primary colors (RGB) of light, and may contain at least one of a red (R) dye, a green (G) dye, and a blue (B) dye, for example.

The color filter portion 200 may be a single layer or a plurality of layers. When the color filter portion 200 is a single layer, the color of the light transmitted through the color filter portion 200 can be a desired color by, for example, the cyan (C) dye, the magenta (M) dye, the yellow (Y) dye, or a mixture of these dyes. When the color filter portion 200 has a plurality of layers, the color of the light transmitted through the color filter portion 200 can be a desired color by, for example, laminating a plurality of layers containing different dyes. For example, when a layer containing the cyan (C) dye and another layer containing the yellow dye (Y) are laminated, the color of the light transmitted through these two layers can be green (G).

FIG. 4 is a view for describing an example of a function of the color filter portion 200 (first color filter portion 200a) according to Embodiment 1. In FIG. 4, light L1 indicated by a white arrow extending from the EML 124 of the first light emitting portion 140a indicates the light emitted from the EML 124 of the first light emitting portion 140a and transmitted through the substrate 100 along the direction perpendicular to the first surface 102 or the second surface 104 of the substrate 100. Light L2 indicated by a white arrow extending from the EML 124 of the second light emitting portion 140b indicates the light emitted from the EML 124 of the second light emitting portion 140b and transmitted through the substrate 100 along the direction perpendicular to the first surface 102 or the second surface 104 of the substrate 100. Light L3 indicated by a white arrow extending from the EML 124 of the third light emitting portion 140c indicates the light emitted from the EML 124 of the third light emitting portion 140c and transmitted through the substrate 100 along the direction perpendicular to the first surface 102 or the second surface 104 of the substrate 100.

The light L1 and the light L2 are transmitted through the first electrode 110 and the substrate 100, and are transmitted through the color filter portion 200. Accordingly, the light L1 and the light L2 are colored by the color filter portion 200. The light L1 and the light L2 are, for example, white light before being transmitted through the color filter portion 200. In this case, the light L1 and the light L2 can be colored differently from white by the transmission through the color filter portion 200. On the other hand, the light L3 is transmitted through the first electrode 110 and the substrate 100, but is not transmitted through the color filter portion 200. Accordingly, the light L3 is not colored by the color filter portion 200. If the light L3 is emitted from the EML 124 of the third light emitting portion 140c as white light, for example, the light L3 is output as white light from the light emitting device 10 (second surface 104 of the substrate 100). Alternatively, the light L3 may be prevented from being output to the outside of the light emitting device 10 by, for example, disposing a light shielding member in a region of the second surface 104 of the substrate 100 overlapping with the third light emitting portion 140c. Thus, in the present embodiment, the light (in the example shown in FIG. 4, the light L1 and the light L2) emitted from some light emitting portions 140 (first light emitting portion 140a and second light emitting portion 140b) in the light emitting device 10 can be easily colored.

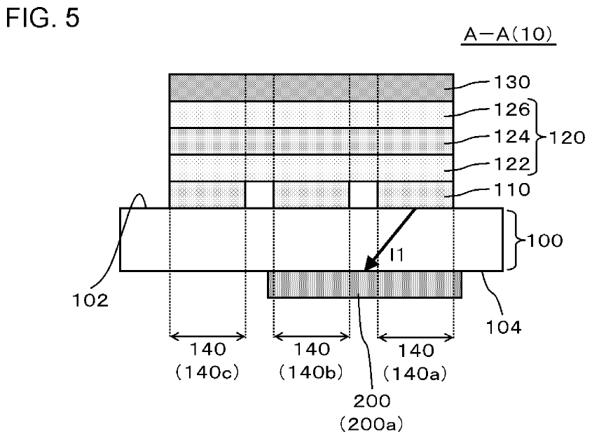

FIG. 5 is a view for describing another example of a function of the color filter portion 200 (first color filter portion 200a) according to Embodiment 1. In FIG. 5, light 11 indicated by a black arrow extending from the center (in FIG. 5, the center of the lower surface of the first electrode 110 is the center in a direction along the first surface 102 of the substrate 100) of the lower surface (in FIG. 5, the lower surface of the first electrode 110 is the surface facing the substrate 100 side) of the first electrode 110 of the first light emitting portion 140a is the light emitted from the EML 124 of the first light emitting portion 140a (in FIG. 5, a path of the light 11 traced from the EML 124 of the first light emitting portion 140a to the first electrode 110 of the first light emitting portion 140a is not shown) and transmitted through the substrate 100 along a direction inclined from the direction perpendicular to the first surface 102 or the second surface 104 of the substrate 100. Most of the light emitted from the EML 124 of the first light emitting portion 140a is transmitted through the substrate 100 along the direction perpendicular to the first surface 102 or the second surface 104 of the substrate 100, as in the light L1 shown in FIG. 4. Some of the light emitted from the EML 124 of the first light emitting portion 140a, however, may be transmitted through the substrate 100 along the direction inclined from the direction perpendicular to the first surface 102 or the second surface 104 of the substrate 100, as in the light 11 shown in FIG. 5. The light 11 reaches a region that is a part of the second surface 104 of the substrate 100 and is positioned between the first light emitting portion 140a and the second light emitting portion 140b when viewed from the direction perpendicular to the first surface 102 or the second surface 104 of the substrate 100.

In the present embodiment, the color filter portion 200 overlaps with two light emitting portions 140 (first light emitting portion 140a and second light emitting portion 140b). In other words, the light emitting portion 140 and the color filter portion 200 do not have a one-to-one correspondence, and some color filter portions 200 (first color filter portion 200a) correspond to the plurality of light emitting portions 140 (first light emitting portion 140a and second light emitting portion 140b). In this case, a plurality of color filter portions having the same color can be connected to each other to correspond to the plurality of light emitting portions 140 (first light emitting portion 140a and second light emitting portion 140b) without being spaced apart from each other.

If the plurality of color filter portions having the same color are provided to correspond to the plurality of light emitting portions 140 (first light emitting portion 140a and second light emitting portion 140b) and spaced apart from each other, there is a possibility that the light 11 leaks to the outside of the light emitting device 10 through a space between the adjacent color filter portions having the same color. On the other hand, in the present embodiment, it is not necessary to consider that the light 11 leaks to the outside of the light emitting device 10 without being transmitted through the color filter portion 200 (first color filter portion 200a). That is, it is not necessary to consider that the light (for example, the light 11) emitted from the adjacent light emitting portions 140 overlapping with the common color filter portion 200 and reaching the region that is a part of the second surface 104 of the substrate 100 and that is positioned between the adjacent light emitting portions 140 when viewed from the direction perpendicular to the first surface 102 or the second surface 104 of the substrate 100, leaks to the outside of the light emitting device 10 without being transmitted through the color filter portion 200.

Further, in the present embodiment, a distance in the direction along the first surface 102 of the substrate 100 between the adjacent light emitting portions 140 (for example, first light emitting portion 140a and second light emitting portion 140b) overlapping with the common color filter portion 200 (first color filter portion 200a) may be shortened. Even in this case, it is not necessary to consider that the light (for example, the light 11) emitted from the adjacent light emitting portions 140 and reaching the region that is a part of the second surface 104 of the substrate 100 and that is positioned between the adjacent light emitting portions 140 when viewed from the direction perpendicular to the first surface 102 or the second surface 104 of the substrate 100, leaks to the outside of the light emitting device 10 without being transmitted through the color filter portion 200.

The layout of the color filter portion 200 (first color filter portion 200a) is not limited to the example shown in FIG. 3, and may be the following layout, for example.

The color filter portion 200 may overlap with only one light emitting portion 140 of the plurality of light emitting portions 140 (for example, any one of the first light emitting portion 140a, the second light emitting portion 140b, and the third light emitting portion 140c), and may not have to overlap with the remaining light emitting portions 140. In other words, the color filter portion 200 overlaps with at least one light emitting portion 140. Even in this case, it is possible to easily color the light emitted from some light emitting portions 140 in the light emitting device 10.

The color filter portion 200 may overlap with all of the light emitting portions 140 (first light emitting portion 140a, second light emitting portion 140b, and third light emitting portion 140c) of the plurality of light emitting portions 140. For example, if the light emitting device 10 includes only two light emitting portions 140, the color filter portion 200 may overlap with two light emitting portions 140. In other words, the color filter portion 200 overlaps with at least two light emitting portions 140. Also in this case, unlike when the plurality of color filter portions having the same color are provided to correspond to the plurality of light emitting portions 140 and spaced apart from each other, it is not necessary to consider that the light (for example, the light 11 shown in FIG. 5) emitted from the adjacent light emitting portions 140 overlapping with the common color filter portion 200 and reaching the region that is a part of the second surface 104 of the substrate 100 and that is positioned between the adjacent light emitting portions 140 when viewed from the direction perpendicular to the first surface 102 or the second surface 104 of the substrate 100, leaks to the outside of the light emitting device 10 without being transmitted through the color filter portion 200.

Next, an example of a method of manufacturing the light emitting device 10 will be described.

First, the plurality of light emitting portions 140 are formed over the first surface 102 of the substrate 100. Specifically, first, the plurality of first electrodes 110 are formed by, for example, patterning. Then, each layer (HTL 122, EML 124, and ETL 126) of the organic layer 120 is formed by, for example, vapor deposition or application. Then, the second electrode 130 is formed by, for example, vapor deposition.

Then, the color filter portion 200 is formed over the second surface 104 of the substrate 100. The color filter portion 200 is formed by, for example, applying with an inkjet or the like. When the color filter portion 200 is formed by application, the color filter portion 200 can be formed without using a mask. Therefore, when the color filter portion 200 is formed by application, a degree of freedom in the shape of the color filter portion 200 is improved as compared with when the color filter portion 200 is formed by vapor deposition requiring a mask. The color filter portion 200, however, may be formed by a method different from application, for example, by vapor deposition.

The manufacturing method of the light emitting device 10 is not limited to the example described above. For example, first, the color filter portion 200 may be formed over the second surface 104 of the substrate 100, and then the plurality of light emitting portions 140 may be formed over the first surface 102 of the substrate 100.

In the present embodiment, the light emitted from some light emitting portions 140 in the light emitting device 10 is colored by an optical filter (that is, the color filter portion 200) that gives the color indicated by the contained dye. However, the light emitting device 10 may include, instead of the color filter portion 200, an optical filter (for example, a bandpass filter (BPF), a long pass filter (LPF), or a short pass filter (SPF)) that blocks the light of a specific wavelength region (or selectively transmits the light of a specific wavelength region). In this case, the light of the specific wavelength region of the light emitted from some light emitting portions 140 in the light emitting device 10 can be shielded or transmitted.

### Embodiment 2

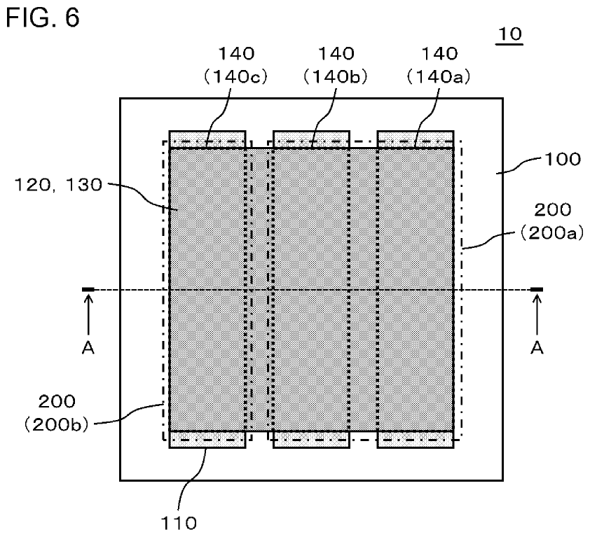

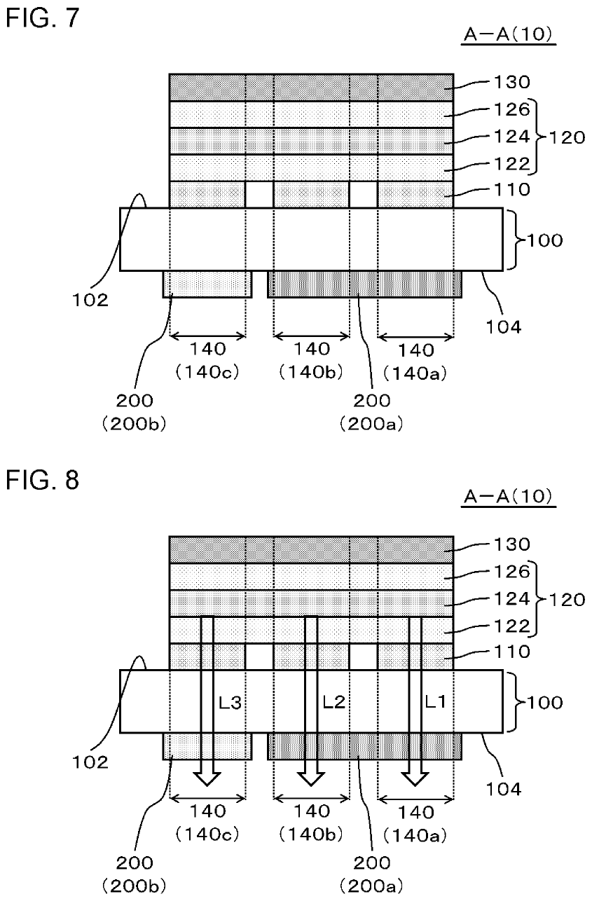

FIG. 6 is a plan view of the light emitting device 10 according to Embodiment 2, and corresponds to FIG. 1 of Embodiment 1. FIG. 7 is a cross-sectional view taken along the line A-A of FIG. 6, and corresponds to FIG. 3 of Embodiment 1. The light emitting device 10 according to Embodiment 2 is the same as the light emitting device 10 according to Embodiment 1 except the following points.

The light emitting device 10 includes a plurality of color filter portions 200. The plurality of color filter portions 200 include a first color filter portion 200a and a second color filter portion 200b. The first color filter portion 200a and the second color filter portion 200b are spaced apart from each other. The second color filter portion 200b has a color different from a color of the first color filter portion 200a. The first color filter portion 200a overlaps with two light emitting portions 140, that is, the first light emitting portion 140a and the second light emitting portion 140b. On the other hand, the second color filter portion 200b overlaps with one light emitting portion 140, that is, the third light emitting portion 140c. Thus, the number of light emitting portions 140 overlapping with the first color filter portion 200a and the number of light emitting portions 140 overlapping with the second color filter portion 200b are different from each other. In other words, each light emitting portion 140 and each color filter portion 200 do not have a one-to-one correspondence, and some color filter portions 200 (first color filter portion 200a) correspond to the plurality of light emitting portions 140 (first light emitting portion 140a and second light emitting portion 140b).

FIG. 8 is a view for describing an example of functions of the plurality of color filter portions 200 (first color filter portion 200a and second color filter portion 200b) according to Embodiment 2, and corresponds to FIG. 4 of Embodiment 1.

The light L1 and the light L2 are transmitted through the first electrode 110 and the substrate 100, and are transmitted through the first color filter portion 200a. Accordingly, the light L1 and the light L2 are colored by the first color filter portion 200a. The light L1 and the light L2 are, for example, white light before being transmitted through the first color filter portion 200a. In this case, the light L1 and the light L2 can be colored differently from white by the transmission through the first color filter portion 200a. The light L3 is transmitted through the first electrode 110 and the substrate 100, and are transmitted through the second color filter portion 200b. Accordingly, the light L3 is colored by the second color filter portion 200b. The light L3 is, for example, white light before being transmitted through the second color filter portion 200b. In this case, the light L3 can be colored differently from white by the transmission through the second color filter portion 200b.

Also in the present embodiment, it is possible to easily color the light (in the example shown in FIG. 8, the light L1 and the light L2) emitted from some light emitting portions 140 (first light emitting portion 140a and second light emitting portion 140b) in the light emitting device 10 and the light (in the example shown in FIG. 8, the light L3) emitted from some other light emitting portions 140 (third light emitting portion 140c) in the light emitting device 10. Further, in the present embodiment, unlike when the plurality of color filter portions having the same color are provided to correspond to the plurality of light emitting portions 140 (first light emitting portion 140a and second light emitting portion 140b) and spaced apart from each other, it is not necessary to consider that the light (for example, the light 11 shown in FIG. 5) emitted from the adjacent light emitting portions 140 overlapping with the common color filter portion 200 and reaching the region that is a part of the second surface 104 of the substrate 100 and that is positioned between the adjacent light emitting portions 140 when viewed from the direction perpendicular to the first surface 102 or the second surface 104 of the substrate 100, leaks to the outside of the light emitting device 10 without being transmitted through the color filter portion 200.

In the present embodiment, any of the plurality of light emitting portions 140 overlaps with any of the plurality of color filter portions 200. However, as in Embodiment 1, at least one of the plurality of light emitting portions 140 may not overlap with the color filter portion.

In the present embodiment, the first color filter portion 200a overlaps with two light emitting portions 140 (first light emitting portion 140a and second light emitting portion 140b), and the second color filter portion 200b overlaps with one light emitting portion 140 (third light emitting portion 140c). However, the number of light emitting portions 140 overlapping with the first color filter portion 200a and the number of light emitting portions 140 overlapping with the second color filter portion 200b may be different from each other, and the first color filter portion 200a and the second color filter portion 200b may overlap with the plurality of light emitting portions 140, unlike the present embodiment.

In the present embodiment, the plurality of color filter portions 200 include two color filter portions 200. However, the plurality of color filter portions 200 may include three or more color filter portions 200. When the plurality of color filter portions 200 include three or more color filter portions 200, at least two color filter portions 200 of the three or more color filter portions 200 have the same configuration as the first color filter portion 200a and the second color filter portion 200b of the present embodiment. Three or more color filter portions 200 may have different colors from each other, or may have the same color as each other.

### EXAMPLES

### Example 1

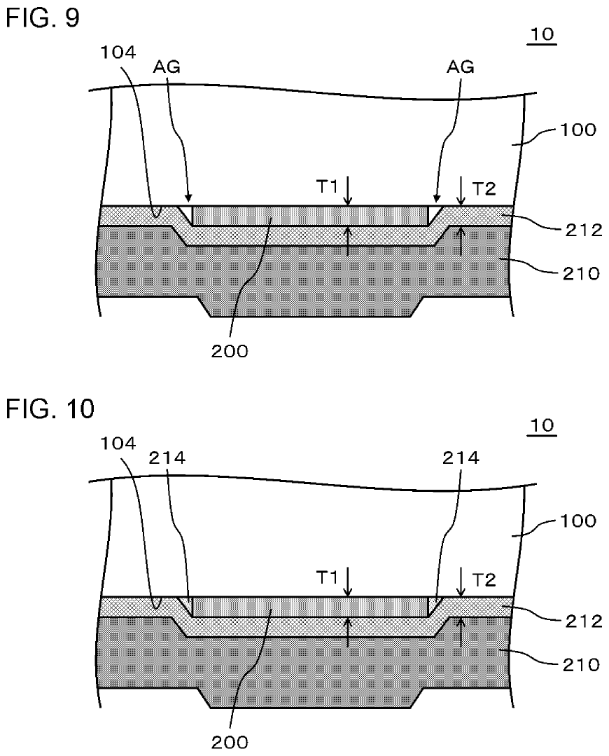

FIG. 9 is an enlarged cross-sectional view of a part of the light emitting device 10 according to Example 1. FIG. 9 shows a cross section perpendicular to the second surface 104 of the substrate 100, and corresponds to, for example, an enlarged view of a part of the cross section shown in FIG. 3. In FIG. 9, the color filter portion 200 and its periphery are enlarged. The light emitting device 10 according to Example 1 is the same as the light emitting device 10 according to Embodiment 1 except the following points.

The light emitting device 10 includes a polarizing plate 210 and an adhesive 212. The polarizing plate 210 is adhered to the second surface 104 of the substrate 100 through the adhesive 212. The polarizing plate 210 and the adhesive 212 cover the second surface 104 of the substrate 100 and the color filter portion 200. When the polarizing plate 210 is provided, the reflection of the light emitting portion 140 when the light emitting device 10 is viewed from the second surface 104 side of the substrate 100 can be reduced as compared with when the polarizing plate 210 is not provided.

The polarizing plate 210 and the adhesive 212 cover a region of the second surface 104 of the substrate 100 where the color filter portion 200 is not positioned, as well as the color filter portion 200. For example, as in Embodiment 1 (FIG. 3), when the second surface 104 of the substrate 100 includes a region where a color filter portion is not positioned, the region overlapping with at least one light emitting portion 140 (third light emitting portion 140c) of the plurality of light emitting portions 140 when viewed from the direction perpendicular to the first surface 102 or the second surface 104 of the substrate 100, (region overlapping with the third light emitting portion 140c when viewed from the direction perpendicular to the first surface 102 or the second surface 104), the polarizing plate 210 and the adhesive 212 covers the region of the second surface 104 of the substrate 100. In this case, the region of the second surface 104 of the substrate 100 is in contact with the adhesive 212.

When a thickness T1 of the color filter portion 200 (thickness in the direction perpendicular to the second surface 104 of the substrate 100) and a thickness T2 of the adhesive 212 (thickness in the direction perpendicular to the second surface 104 of the substrate 100) are equal or close to each other, such as 0.75≤T2/T1≤1.25, the adhesive 212 does not smoothly cover a side surface of the color filter portion 200, and a void AG may be formed around the color filter portion 200 (in the example shown in FIG. 9, the portions positioned on the right and left sides of the color filter portion 200). The void AG contains bubbles, for example. The void AG may be present or may be filled with a specific material as described below.

### Example 2

FIG. 10 is an enlarged cross-sectional view of a part of the light emitting device 10 according to Example 2, and corresponds to FIG. 9 of Example 1. The light emitting device 10 according to Example 2 is the same as the light emitting device 10 according to Example 1 except the following points.

The light emitting device 10 includes a transparent resin 214. A transmittance of the visible light of the transparent resin 214 is, for example, equal to or more than 75% and equal to or less than 100%. In the present example, the void AG (FIG. 9) described in Example 1 is filled with the transparent resin 214. In other words, the transparent resin 214 is covered with the adhesive 212 around the color filter portion 200 (in the example shown in FIG. 10, the portions positioned on the right and left sides of the color filter portion 200). The transparent resin 214 is an acrylic resin, for example. When the light emitting device 10 is viewed from the second surface 104 side of the substrate 100, and the void AG is not filled with the transparent resin 214, the void AG may be visible, for example, in a white line. In the present example, it is possible to reduce the visibility of the void AG by the transparent resin 214.

In the present example, the transparent resin 214 is positioned around the color filter portion 200 (in the example shown in FIG. 10, the portions positioned on the right and left sides of the color filter portion 200).

As in Embodiment 1 (FIG. 3), when the second surface 104 of the substrate 100 includes a region where a color filter portion is not positioned, the region overlapping with at least one light emitting portion 140 (third light emitting portion 140c) of the plurality of light emitting portions 140 when viewed from the direction perpendicular to the first surface 102 or the second surface 104 of the substrate 100 (region overlapping with the third light emitting portion 140c when viewed from the direction perpendicular to the first surface 102 or the second surface 104), a part of the transparent resin 214 may cover the region of the second surface 104 of the substrate 100. In this case, the region of the second surface 104 of the substrate 100 is in contact with at least one of the adhesive 212 and the transparent resin 214.

Next, an example of a method of manufacturing the light emitting device 10 will be described.

First, the color filter portion 200 is formed over the second surface 104 of the substrate 100. Then, the transparent resin 214 is formed around the color filter portion 200 (in the example shown in FIG. 10, the portions positioned on the right and left sides of the color filter portion 200). Then, the polarizing plate 210 is adhered to the second surface 104 of the substrate 100 through the adhesive 212.

Then, the light emitting device 10 may be subjected to autoclave processing. Even if the void AG remains after the formation of the transparent resin 214, the void AG can be further removed by the autoclave processing.

### Example 3

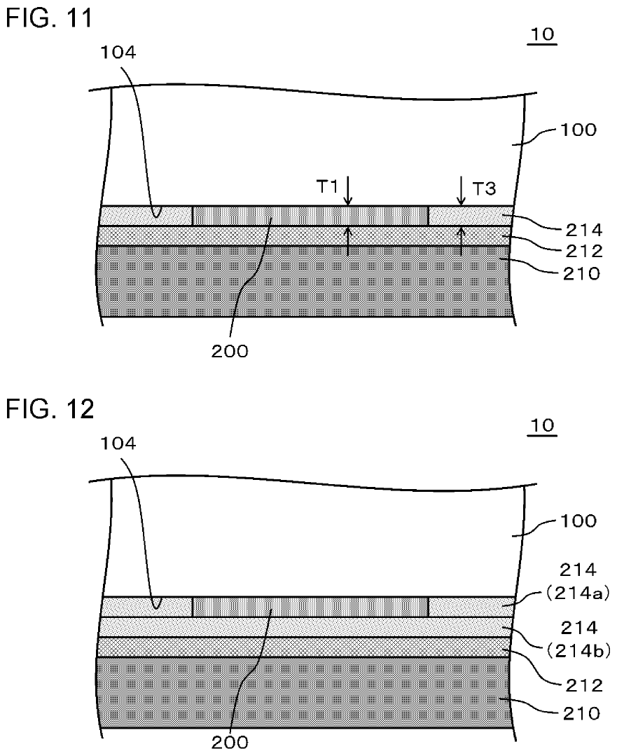

FIG. 11 is an enlarged cross-sectional view of a part of the light emitting device 10 according to Example 3, and corresponds to FIG. 10 of Example 2. The light emitting device 10 according to Example 3 is the same as the light emitting device 10 according to Example 2 except the following points.

When viewed from the direction perpendicular to the second surface 104 of the substrate 100, an area of the transparent resin 214 according to the present example is larger than an area of the transparent resin 214 according to Example 2 (FIG. 10). For example, the transparent resin 214 extends over the entire or most of the region of the polarizing plate 210 not overlapping with the color filter portion 200. For example, when viewed from the direction perpendicular to the second surface 104 of the substrate 100, the transparent resin 214 may be positioned over equal to or more than 85% and equal to or less than 100% of the total area of the polarizing plate 210 minus the area of the portion of the polarizing plate 210 overlapping with the color filter portion 200 (when the light emitting device 10 includes the plurality of color filter portions 200, all of the color filter portions 200). Also in the present example, the transparent resin 214 is in contact with the second surface 104 of the substrate 100.

The thickness T1 of the color filter portion 200 (thickness in the direction perpendicular to the second surface 104 of the substrate 100) and a thickness T3 of the transparent resin 214 (thickness in the direction perpendicular to the second surface 104 of the substrate 100) are equal or close to each other, such as 0.75≤T3/T1≤1.25. Accordingly, the surface (lower surface) of the color filter portion 200 at the polarizing plate 210 side and the surface (lower surface) of the transparent resin 214 at the polarizing plate 210 side can be flush with each other or brought close to each other. Accordingly, the portions of the polarizing plate 210 and the adhesive 212 covering the color filter portion 200 can be made flatter or closer to flat as compared with Example 2 (FIG. 10).

### Example 4

FIG. 12 is an enlarged cross-sectional view of a part of the light emitting device 10 according to Example 4, and corresponds to FIG. 11 of Example 3. The light emitting device 10 according to Example 4 is the same as the light emitting device 10 according to Example 3 except the following points.

The transparent resin 214 includes a first transparent resin 214a and a second transparent resin 214b. Like the transparent resin 214 shown in FIG. 11, the first transparent resin 214a extends over the entire or most of the region of the polarizing plate 210 not overlapping with the color filter portion 200. The second transparent resin 214b covers the color filter portion 200 and the first transparent resin 214a. In the present example, the surface (lower surface) of the second transparent resin 214b at the polarizing plate 210 side can be flattened or brought close to flat by the first transparent resin 214a and the second transparent resin 214b. Accordingly, the portions of the polarizing plate 210 and the adhesive 212 covering the color filter portion 200 can be made flatter or closer to flat as compared with Example 2 (FIG. 10).

In the present example, the first transparent resin 214a is formed around the color filter portion 200 (in the example shown in FIG. 12, the portions positioned on the right and left sides of the color filter portion 200), and then the second transparent resin 214b is formed. In this case, the first transparent resin 214a and the second transparent resin 214b may contain the same material (same resin), or may contain different materials (different resins). A method of forming the first transparent resin 214a and the second transparent resin 214b, however, are not limited to the example described above. For example, the first transparent resin 214a and the second transparent resin 214b may be collectively formed. In this case, the first transparent resin 214a is a part of the transparent resin 214, the second transparent resin 214b is another part of the transparent resin 214, and the part of the transparent resin 214 (first transparent resin 214a) and the another part of the transparent resin 214 (second transparent resin 214b) contain the same material (the same resin).

### Example 5

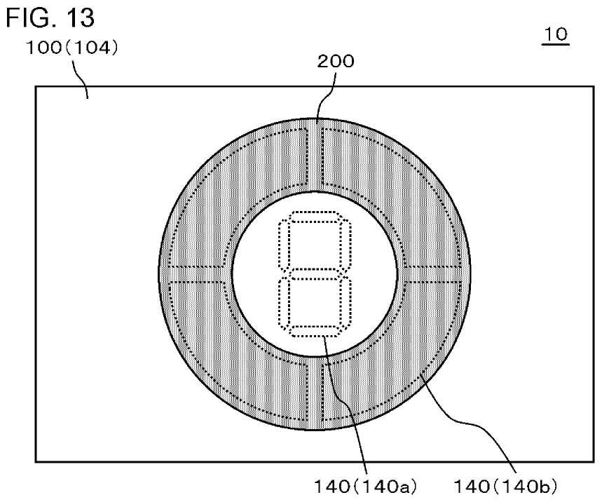

FIG. 13 is a plan view of the second surface 104 of the substrate 100 of the light emitting device 10 according to Example 5. In FIG. 13, the light emitting portion 140 is shown by being transmitted through a broken line. The light emitting device 10 according to Example 5 is the same as the light emitting device 10 according to Embodiment 1 except the following points.

The light emitting device 10 includes the plurality of light emitting portions 140. The plurality of light emitting portions 140 include seven first light emitting portions 140a and four second light emitting portions 140b. Each of the seven first light emitting portions 140a and the four second light emitting portions 140b is a segment type light emitting portion. The seven first light emitting portions 140a are seven segment displays and are capable of displaying Arabic numerals 0 to 9. The four second light emitting portions 140b surround the seven first light emitting portions 140a. Each second light emitting portion 140b has a circular sector shape.

The color filter portion 200 overlaps with the four second light emitting portions 140b without overlapping with the seven first light emitting portions 140a. The color filter portion 200 is positioned to surround the seven first light emitting portions 140a. Accordingly, it is possible to easily color the light emitted from some light emitting portions 140 (four second light emitting portions 140b) in the light emitting device 10. Further, it is possible to effectively use the light (for example, white light) emitted from some other light emitting portions 140 (seven first light emitting portions 140a) of the seven first light emitting portions 140a and the four second light emitting portions 140b.

The layouts of the color filter portion 200, the seven first light emitting portions 140a, and the four second light emitting portions 140b are not limited to the present example. For example, the color filter portion 200 may overlap with the seven first light emitting portions 140a without overlapping with the four second light emitting portions 140b. In addition, as in Embodiment 2, one of the first color filter portion 200a and the second color filter portion 200b may overlap with the seven first light emitting portions 140a, and the other of the first color filter portion 200a and the second color filter portion 200b may overlap with the four second light emitting portions 140b.

As above, the embodiments and the examples are described with reference to the drawings, but these are examples of the present invention, and various other configurations other than the embodiments and the examples described above can be adopted.

For example, in the embodiments and examples, the light emitting portion 140 of the light emitting device 10 is the organic electroluminescence (EL) element having the emissive layer (EML 124). However, the light emitting portion 140 of the light emitting device 10 may be a light emitting portion different from the organic EL element, such as an inorganic EL element or a semiconductor light-emitting diode (LED).

This application claims priority based on Japanese Patent Application No. 2019-164327 filed on Sep. 10, 2019, the entire disclosure of which is incorporated herein by reference.

### REFERENCE SIGNS LIST

10: light emitting device
100: substrate
102: first surface
104: second surface
110: first electrode
120: organic layer
122: hole transport layer (HTL)
124: emissive layer (EML)
126: electron transport layer (ETL)
130: second electrode
140: light emitting portion
140a: first light emitting portion
140b: second light emitting portion
140c: third light emitting portion
200: color filter portion
200a: first color filter portion
200b: second color filter portion
210: polarizing plate
212: adhesive
214: transparent resin
214a: first transparent resin
214b: second transparent resin

1. A light emitting device comprising:
a translucent substrate comprising a first surface and a second surface opposite to the first surface;
a plurality of light emitting portions positioned over the first surface of the substrate; and
a first color filter portion positioned over the second surface of the substrate and overlapping with at least one light emitting portion of the plurality of light emitting portions when viewed from a direction perpendicular to the first surface or the second surface,
wherein the second surface of the substrate comprises a region where a color filter portion is not positioned, the region overlapping with at least one light emitting portion of the plurality of light emitting portions when viewed from the direction perpendicular to the first surface or the second surface.

2. A light emitting device comprising:
a translucent substrate comprising a first surface and a second surface opposite to the first surface;
a plurality of light emitting positioned over the first surface of the substrate; and
a first color filter portion positioned over the second surface of the substrate and overlapping with at least two light emitting portions of the plurality of light emitting portions when viewed from a direction perpendicular to the first surface or the second surface.

3. The light emitting device according to claim 2, further comprising:
a second color filter portion positioned over the second surface of the substrate and overlapping with at least other one light emitting portion of the plurality of light emitting portions when viewed from the direction perpendicular to the first surface or the second surface, the second color filter portion having color different from color of the first color filter portion,
wherein the number of light emitting portions overlapping with the first color filter portion and the number of light emitting portions overlapping with the second color filter portion are different from each other.

4. The light emitting device according to claim 1, further comprising:
a polarizing plate covering the second surface of the substrate and the first color filter portion.

5. The light emitting device according to claim 4,
wherein the polarizing plate is adhered to the second surface of the substrate through an adhesive, and
the light emitting device further comprises a transparent resin covered with the adhesive around the first color filter portion.

6. The light emitting device according to claim 4,
wherein the polarizing plate covers a region of the second surface of the substrate where the color filter portion is not positioned, the region overlapping with at least one light emitting portion of the plurality of light emitting portions when viewed from the direction perpendicular to the first surface or the second surface.

7. The light emitting device according to claim 1,
wherein each of the plurality of light emitting portions is a segment type light emitting portion.

8. The light emitting device according to claim 1,
wherein the first color filter portion comprises at least one of a cyan dye, a magenta dye, and a yellow dye.

9. The light emitting device according to claim 1,
wherein the light emitting portion is an organic EL element.

10. A light emitting device comprising:
a translucent substrate comprising a first surface and a second surface opposite to the first surface;
a plurality of light emitting portions positioned over the first surface of the substrate;
a first color filter portion positioned over the second surface of the substrate and overlapping with at least one light emitting portion of the plurality of light emitting portions when viewed from a direction perpendicular to the first surface or the second surface; and
a polarizing plate covering the second surface of the substrate and the first color filter portion and adhered to the second surface of the substrate through an adhesive,
wherein the second surface of the substrate includes a region in contact with the adhesive, the region overlapping with at least one light emitting portion of the plurality of light emitting portions when viewed from the direction perpendicular to the first surface or the second surface.

11. A light emitting device comprising:
a translucent substrate comprising a first surface and a second surface opposite to the first surface;
a plurality of light emitting portions positioned over the first surface of the substrate;
a first color filter portion positioned over the second surface of the substrate and overlapping with at least one light emitting portion of the plurality of light emitting portions when viewed from a direction perpendicular to the first surface or the second surface;
a polarizing plate covering the second surface of the substrate and the first color filter portion and adhered to the second surface of the substrate through an adhesive; and
a transparent resin covered with the adhesive around the first color filter portion,
wherein the second surface of the substrate comprises a region in contact with at least one of the adhesive and the transparent resin, the region overlapping with at least one light emitting portion of the plurality of light emitting portions when viewed from the direction perpendicular to the first surface or the second surface.
